(19) United States
(12) Patent Application Publication
(10) Pub. No.: US 2025/0385144 A1
(43) Pub. Date: Dec. 18, 2025

(54) SEMICONDUCTOR DEVICE

(71) Applicant: Mitsubishi Electric Corporation, Tokyo (JP)

(72) Inventor: Masaomi MIYAZAWA, Tokyo (JP)

(73) Assignee: Mitsubishi Electric Corporation, Tokyo (JP)

(21) Appl. No.: 19/076,944

(22) Filed: Mar. 11, 2025

(30) Foreign Application Priority Data
Jun. 13, 2024 (JP) 2024-095587

(51) Int. Cl. H01L 23/057; H01L 23/498; H01R 9/24

(52) U.S. Cl. CPC H01L 23/057; H01L 23/498; H01R 9/2425

(57) ABSTRACT

A semiconductor device includes a semiconductor chip, a first terminal, a case, and a second terminal. The semiconductor chip includes the first electrode and the second electrode. The first terminal is electrically connected to the first electrode of the semiconductor chip. The case accommodates the semiconductor chip. A part of the first terminal is embedded in the case. The second terminal includes a conductive portion electrically connected to the second electrode of the semiconductor chip and a projection electrically insulated from the conductive portion. The first terminal includes a through hole provided in a portion exposed from the case. The projection is inserted into the through hole.

### BACKGROUND

### Technical Field

The present disclosure relates to a semiconductor device.

### Description of the Background Art

A semiconductor device described in Japanese Patent Application Laid-Open No. 2017-126682 includes a surrounding resin case in which a plurality of terminal holders is formed, an external terminal held by the terminal holder, and a terminal locking member fixed to an upper end of the surrounding resin case. The terminal locking member holds the external terminal so that the external terminal does not come out toward the upper end of the surrounding resin case.

In the semiconductor device described in Japanese Patent Application Laid-Open No. 2017-126682, the external terminal is inserted into the surrounding resin case and fixed by the terminal locking member. In an assembly step, in a case where the external terminal held by the surrounding resin case is inclined, it is difficult to cover the upper end of the surrounding resin case with the terminal locking member, and workability is deteriorated.

### SUMMARY

An object of the present disclosure is to provide a semiconductor device that reduces inclination or positional deviation of a terminal.

A semiconductor device of the present disclosure includes a semiconductor chip, a first terminal, a case, and a second terminal. The semiconductor chip includes a first electrode and a second electrode. The first terminal is electrically connected to the first electrode of the semiconductor chip. The case accommodates the semiconductor chip. A part of the first terminal is embedded in the case. The second terminal includes a conductive portion electrically connected to the second electrode of the semiconductor chip and a projection electrically insulated from the conductive portion. The first terminal includes a through hole provided in a portion exposed from the case. The projection is inserted into the through hole.

Provided is a semiconductor device that reduces inclination or positional deviation of a terminal.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a perspective view illustrating a configuration of a semiconductor device according to a first preferred embodiment;

FIG. 2 is a side view illustrating an internal configuration of the semiconductor device;

FIG. 3 is a top view illustrating a configuration of wiring inside the semiconductor device;

FIG. 4 is a perspective view illustrating a configuration of a case;

FIG. 5 is a perspective view illustrating a configuration of an insert terminal and an outsert terminal;

FIG. 6 is a sectional view illustrating the configuration of the insert terminal and the outsert terminal;

FIG. 7 is a perspective view illustrating a configuration of the insert terminal;

FIG. 8 is a perspective view illustrating a configuration of the outsert terminal;

FIG. 9 is a perspective view illustrating a configuration of a projection and a through hole;

FIG. 10 is a diagram illustrating an equivalent circuit for one phase included in a three-level inverter;

FIG. 11 is a perspective view illustrating a configuration of an insert terminal and an outsert terminal according to a second preferred embodiment;

FIG. 12 is a perspective view illustrating a configuration of an insert terminal and an outsert terminal according to a third preferred embodiment;

FIG. 13A is a perspective view illustrating a configuration of the outsert terminal, FIG. 13B is a perspective view illustrating a configuration of an external connection end of the outsert terminal, and FIG. 13C is a perspective view illustrating a configuration of a hook;

FIG. 14 is a perspective view illustrating a configuration of an outsert terminal according to a fourth preferred embodiment;

FIG. 15 is a perspective view illustrating a configuration of a conductive portion of the outsert terminal;

FIG. 16 is a perspective view illustrating a configuration of an outsert terminal according to a fifth preferred embodiment;

FIG. 17 is a perspective view illustrating a configuration of the conductive portion and the projection of the outsert terminal;

FIG. 18 is a side view illustrating a configuration of an insert terminal and an outsert terminal according to a sixth preferred embodiment;

FIG. 19 is a side view illustrating a configuration of an insert terminal and an outsert terminal according to a seventh preferred embodiment;

FIG. 20 is a side view illustrating a configuration of an insert terminal and an outsert terminal according to an eighth preferred embodiment;

FIG. 21 is a perspective view illustrating a configuration of an insert terminal and an outsert terminal according to a ninth preferred embodiment;

FIG. 22 is a perspective view illustrating a configuration of an insert terminal and an outsert terminal according to a tenth preferred embodiment; and

FIG. 23 is a perspective view illustrating a configuration of an insert terminal and an outsert terminal according to an eleventh preferred embodiment.

### DESCRIPTION OF THE PREFERRED EMBODIMENTS

### First Preferred Embodiment

Hereinafter, preferred embodiments will be described with reference to the accompanying drawings. Characteristics described in the following preferred embodiments are merely examples, and all the characteristics are not necessarily essential. In the following description, similar constituent elements in a plurality of preferred embodiments are denoted by the same or similar reference numerals, and different constituent elements will be mainly described. In the following description, specific positions and directions such as “upper”, “lower”, “left”, “right”, “front”, or “back” do not necessarily coincide with positions and directions in practice.

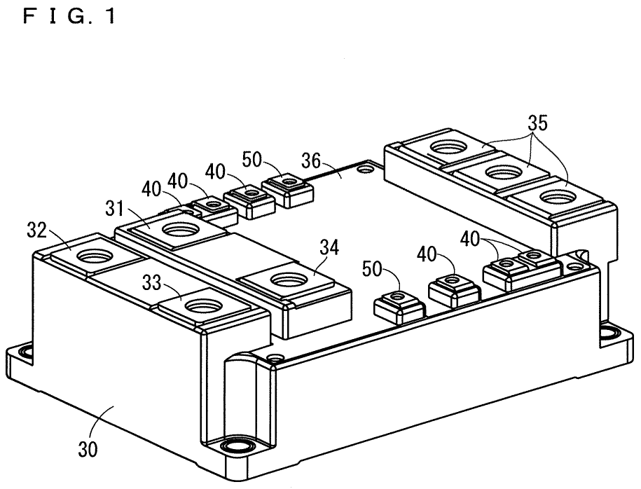

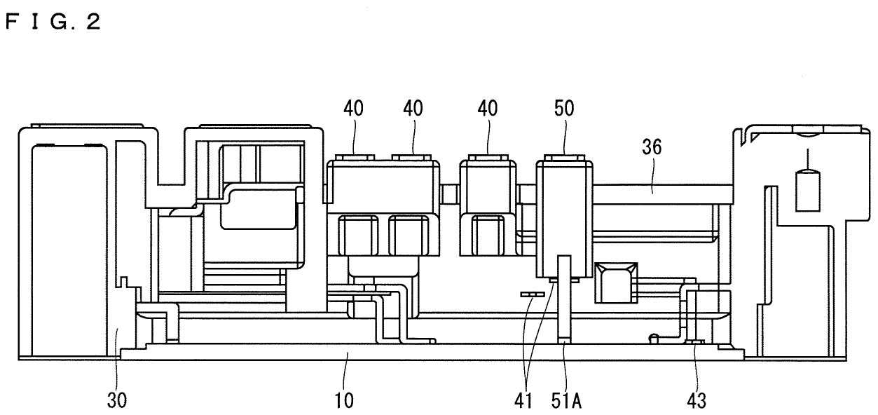

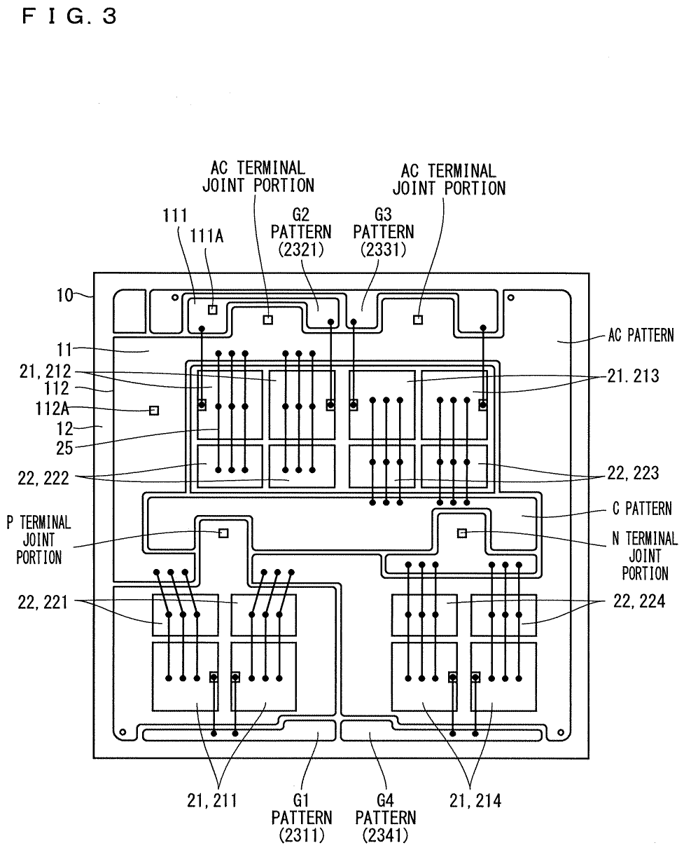

FIG. 1 is a perspective view illustrating a configuration of a semiconductor device according to a first preferred embodiment. FIG. 2 is a side view illustrating an internal configuration of the semiconductor device. FIG. 3 is a top view illustrating a configuration of wiring inside the semiconductor device. The semiconductor device is, for example, a power module.

The semiconductor device includes a conductive layer-attached insulating substrate 10, a semiconductor chip 20 (a semiconductor chip 21 and a semiconductor chip 22 in FIG. 3 are combined into the semiconductor chip 20), a case 30, an insert terminal 40 (first terminal), and an outsert terminal 50 (second terminal). In the first preferred embodiment, fixing a terminal with an insulating portion, which is molded as a separate component from the case 30, at a predetermined position of the case 30 is referred to as “outsert”, and the outserted terminal is referred to as “outsert terminal”.

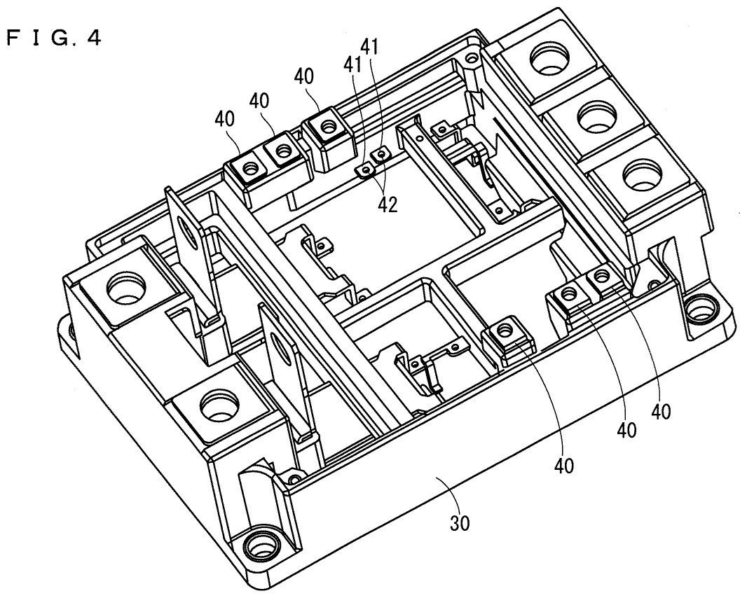

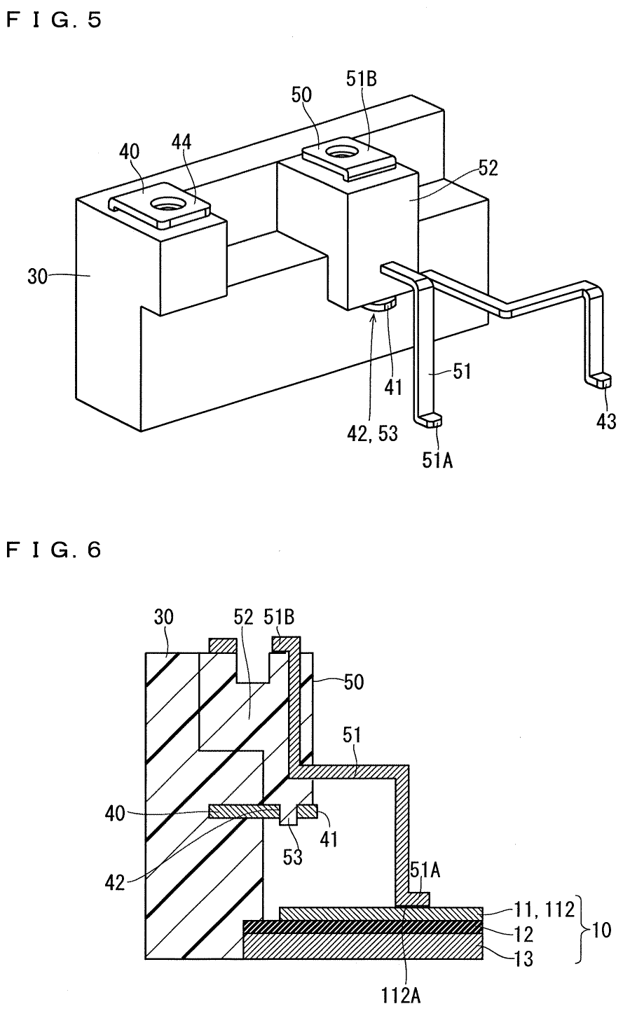

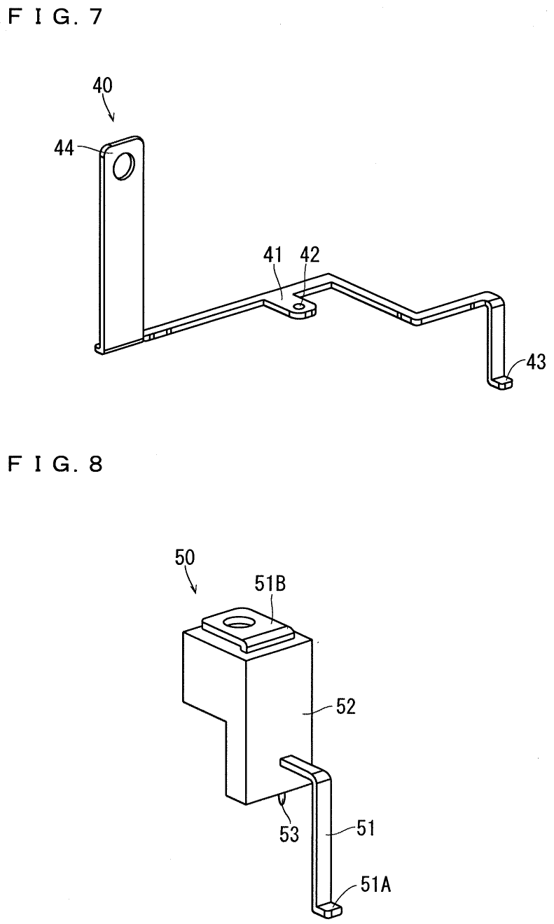

FIG. 4 is a perspective view illustrating a configuration of the case 30. FIG. 5 is a perspective view illustrating a configuration of the insert terminal 40 and the outsert terminal 50. FIG. 6 is a sectional view illustrating the configuration of the insert terminal 40 and the outsert terminal 50. FIG. 7 is a perspective view illustrating a configuration of the insert terminal 40. FIG. 8 is a perspective view illustrating a configuration of the outsert terminal 50.

As illustrated in FIG. 6, the conductive layer-attached insulating substrate 10 includes a conductive layer 11, an insulating layer 12, and a heat dissipation metal layer 13. The conductive layer 11 is provided on an upper surface of the heat dissipating metal layer 13 with an insulating layer 12 interposed therebetween. The insulating layer 12 includes, for example, an insulating material such as ceramic or resin. The conductive layer 11 and the heat dissipating metal layer 13 include, for example, Cu. As illustrated in FIG. 3, the conductive layer 11 includes a first circuit pattern 111 and a second circuit pattern 112. The first circuit pattern 111 is provided with a joint portion 111A to which the insert terminal 40 is joined. The second circuit pattern 112 is provided with a joint portion 112A to which the outsert terminal 50 is joined.

The semiconductor chip 20 includes a first electrode (not illustrated) and a second electrode (not illustrated). The first electrode is electrically connected to the first circuit pattern 111. The second electrode is electrically connected to the second circuit pattern 112. The semiconductor chip 20 is a switching element chip 21 including switching elements 211 to 214 or a diode element chip 22 including diode element 221 to 224.

In a case where the semiconductor chip 20 includes an insulated gate bipolar transistor (IGBT) as the switching elements 211 to 214, the first electrode is any one of a collector electrode, an emitter electrode, or a gate electrode. The second electrode is an electrode different from the first electrode of the collector electrode, the emitter electrode, or the gate electrode.

In a case where the semiconductor chip 20 includes a metal oxide semiconductor field effect transistor (MOSFET) as the switching elements 211 to 214, the first electrode is any one of a drain electrode, a source electrode, or a gate electrode. The second electrode is an electrode different from the first electrode of the drain electrode, the source electrode, or the gate electrode.

In a case where the semiconductor chip 20 includes the diode elements 221 to 224, the first electrode is any one of a cathode electrode or an anode electrode. The second electrode is an electrode different from the first electrode of the cathode electrode or the anode electrode. The diode elements 221 to 224 may be a Schottky barrier diode (SBD) or a PN junction diode (PND).

The semiconductor chip 20 may be a reverse-conducting IGBT (RC-IGBT) chip in which the IGBT and the diode elements 221 to 224 are provided in one chip.

As illustrated in FIGS. 2 and 4, the case 30 has a frame body. The case 30 accommodates the conductive layer 11 of the conductive layer-attached insulating substrate 10 and the semiconductor chip 20 on an inner side of the frame body. The case 30 is joined to the conductive layer-attached insulating substrate 10 with an adhesive (not illustrated). The adhesive is, for example, a thermosetting resin-based adhesive containing an epoxy resin, a phenol resin, or the like as a main component. Alternatively, the adhesive may be an organic adhesive containing silicone rubber as a main component. As illustrated in FIG. 1, a lid 36 is provided on an upper part of the case 30. The lid 36 is fixed to the case 30 with, for example, a screw (not illustrated). The insert terminal 40, the outsert terminal 50, a C terminal 31, a P terminal 32, an N terminal 33, a C terminal 34, and an AC terminal 35 electrically connected to the semiconductor chip 20 are exposed from upper surfaces of the case 30 and the lid 36. The case 30 and the lid 36 include a synthetic resin such as polyphenylene sulfide (PPS).

The insert terminal 40 is integrated with the case 30 and is manufactured by insert molding. As illustrated in FIGS. 5 to 7, a part of the insert terminal 40 is embedded in the case 30, and the insert terminal 40 is fixed to the case 30. The insert terminal 40 includes metal such as Al, Cu, or Au, for example. The insert terminal 40 includes a protrusion 41, a through hole 42, an internal connection end 43, and an external connection end 44.

The protrusion 41 protrudes to the inner side of the frame body of the case 30 and is exposed from the case 30.

The through hole 42 is provided in the protrusion 41, that is, a portion exposed from the case 30.

The internal connection end 43 extends to the inner side of the frame body of the case 30. The internal connection end 43 is joined to the joint portion 111A of the first circuit pattern 111 illustrated in FIG. 3. That is, the insert terminal 40 is electrically connected to the first electrode of the semiconductor chip 20.

The external connection end 44 is exposed on the upper surface of the case 30 and is configured to be connectable to an external circuit (not illustrated).

The outsert terminal 50 is held by the case 30. The insert terminal 40 is molded integrally with the case 30, but the outsert terminal 50 is not molded integrally with the case 30. For example, as for the case 30 illustrated in FIG. 4, six insert terminals 40 are provided integrally with the case 30. In the semiconductor device illustrated in FIG. 1, two outsert terminals 50 are inserted into the case 30, and a total of eight terminals are provided. As illustrated in FIG. 5, the outsert terminal 50 is inserted and fixed to a predetermined position of the case 30. As illustrated in FIG. 8, the outsert terminal 50 includes a conductive portion 51, an insulating portion 52, and a projection 53.

The conductive portion 51 includes an internal connection end 51A and an external connection end 51B. The internal connection end 51A is joined to the joint portion 112A of the second circuit pattern 112 illustrated in FIG. 3 directly or via solder or the like. That is, the conductive portion 51 of the outsert terminal 50 is electrically connected to the second electrode of the semiconductor chip 20. The external connection end 51B is exposed on an upper surface of the insulating portion 52 and is configured to be connectable to an external circuit. The conductive portion 51 includes metal such as Al, Cu, or Au, for example.

The insulating portion 52 covers a part of the conductive portion 51 and holds the conductive portion 51. In other words, a part of the conductive portion 51 is embedded in the insulating portion 52. The outsert terminal 50 is a component molded so as to integrate the conductive portion 51 and the insulating portion 52. The insulating portion 52 is held by the case 30. The insulating portion 52 includes, for example, a synthetic resin such as polyphenylene sulfide (PPS).

The projection 53 is electrically insulated from the conductive portion 51. The projection 53 according to the first preferred embodiment is provided on the insulating portion 52 and includes the same insulator as the insulating portion 52. Therefore, the projection 53 is easily formed when the conductive portion 51 and the insulating portion 52 are integrally molded.

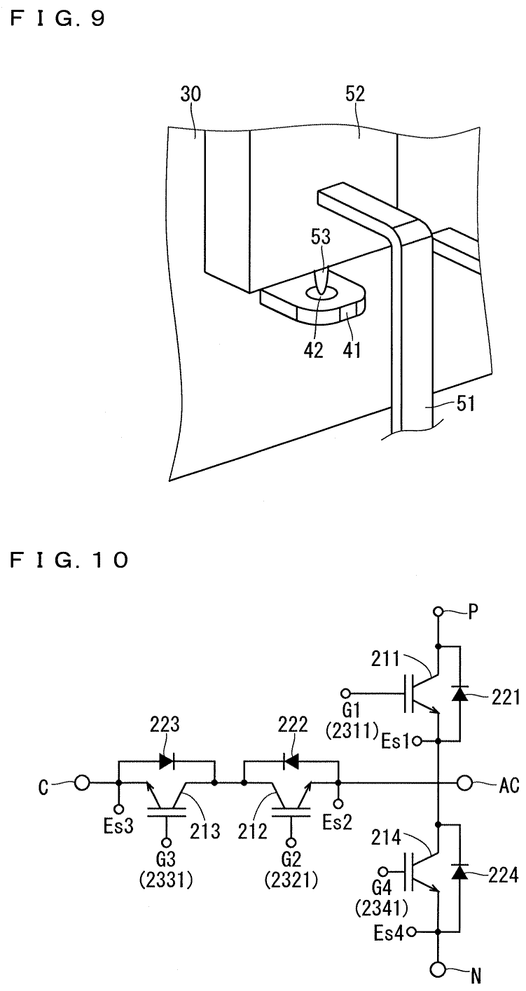

FIG. 9 is a perspective view illustrating a configuration of the projection 53 and the through hole 42. As illustrated in FIGS. 6 and 9, the projection 53 of the outsert terminal 50 is inserted into the through hole 42 of the insert terminal 40. The projection 53 is in direct contact with the through hole 42. Specifically, an outer periphery of the projection 53 is in contact with an inner surface of the through hole 42.

Next, a method of manufacturing a semiconductor device will be described. First, the semiconductor chip 20 is electrically joined to the conductive layer-attached insulating substrate 10.

(1) The semiconductor chip 20 and the conductive layer 11 of the conductive layer-attached insulating substrate 10 are connected by a bonding wire 25. This step is a wire bonding step.

(2) The case 30 and the conductive layer-attached insulating substrate 10 are fixed with an adhesive.

(3) The insert terminal 40 and the first circuit pattern 111 of the conductive layer-attached insulating substrate 10 are joined to each other.

(4) The projection 53 of the outsert terminal 50 is inserted into the through hole 42 of the insert terminal 40.

(5) The outsert terminal 50 and the second circuit pattern 112 of the conductive layer-attached insulating substrate 10 are joined to each other.

The order of execution of step (1) and steps (2) to (5) is not limited. In a case where any component of the insert terminal 40, the outsert terminal 50, or the case 30 covers the bonding wire 25, the wire bonding step at least at that position is preferably executed before steps (2) to (5).

Step (2) is preferably executed simultaneously with or before steps (3) and (5). For example, in a case where the case 30 and the conductive layer-attached insulating substrate 10 are joined to each other by a thermosetting adhesive in step (2), and the terminal and the conductive layer-attached insulating substrate 10 are joined to each other by soldering in steps (3) and (5), the adhesive is thermally cured and soldered by one-time heating.

Step (4) is executed before step (5). That is, the projection 53 is inserted into the through hole 42 before the internal connection end 51A of the outsert terminal 50 and the second circuit pattern 112 of the conductive layer-attached insulating substrate 10 are joined to each other.

Next, the case 30 is filled with a sealing material (not illustrated). The sealing material seals the semiconductor chip 20, the first circuit pattern 111, the second circuit pattern 112, the bonding wire 25, and the internal connection ends 43 and 51A in the case 30. The sealing material is a resin.

Finally, the lid 36 is fixed to the case 30. As described above, the semiconductor device illustrated in FIGS. 1 and 2 is obtained.

In the first preferred embodiment, when the outsert terminal 50 is attached to the case 30, the projection 53 is inserted into the through hole 42. The insert terminal 40 having the through hole 42 is fixed to the case 30. Therefore, inclination and positional deviation of the outsert terminal 50 are reduced. The internal connection end 51A of the outsert terminal 50 is stably joined to the second circuit pattern 112 of the conductive layer-attached insulating substrate 10.

To summarize the above, the semiconductor device according to the first preferred embodiment includes the semiconductor chip 20, the insert terminal 40 (first terminal), the case 30, and the outsert terminal 50 (second terminal). The semiconductor chip 20 includes the first electrode and the second electrode. The insert terminal 40 is electrically connected to the first electrode of the semiconductor chip 20. The case 30 accommodates the semiconductor chip 20. A part of the insert terminal 40 is embedded in the case 30. The outsert terminal 50 includes the conductive portion 51 and the projection 53. The conductive portion 51 is electrically connected to the second electrode of the semiconductor chip 20. The projection 53 is electrically insulated from the conductive portion 51. The insert terminal 40 includes the through hole 42 provided in a portion exposed from the case 30. The projection 53 is inserted into the through hole 42.

Such a configuration reduces the inclination or positional deviation at the time of joining the outsert terminal 50 and the second circuit pattern 112. As a result, workability in a manufacturing process of the semiconductor device is improved. Joining performance between the outsert terminal 50 and the conductive layer 11 is improved, and reliability of the semiconductor device is also improved.

By reducing the inclination or positional deviation at the time of joining the outsert terminal 50 and the second circuit pattern 112, a joining area between the outsert terminal 50 and the second circuit pattern 112 is reduced. The case 30 is downsized, and the density of mounting is increased.

The present disclosure is effective for a semiconductor device including a large number of control terminals such as a power device for a three-level inverter. Alternatively, for example, by adding the outsert terminal 50 to the case 30 of a power device for a two-level inverter, a power device for the three-level inverter can be manufactured. In this case, the case 30 for the two-level inverter and the case 30 for the three-level inverter are made common.

Next, details of a circuit configuration of the semiconductor device and a configuration of the semiconductor chip 20 will be described. As illustrated in FIG. 3, the semiconductor device includes a plurality of semiconductor chips 20. The plurality of semiconductor chips 20 each includes the switching elements 211 to 214 or the diode elements 221 to 224. Here, the semiconductor device is a three-level inverter. FIG. 10 is a diagram illustrating an equivalent circuit for one phase included in the three-level inverter.

The switching elements 211 to 214 illustrated in FIG. 10 are IGBTs, but may be MOSFETs. In a case where the switching elements 211 to 214 are IGBTs, a collector electrode (positive electrode) is provided as a main electrode on a back surface of the semiconductor chip 20, and a gate electrode (control electrode) and an emitter electrode (negative electrode) are provided on a front surface of the semiconductor chip 20. In a case where the switching elements 211 to 214 are MOSFETs, a drain electrode (positive electrode) is provided as a main electrode on the back surface of the semiconductor chip 20, and a gate electrode (control electrode) and a source electrode (negative electrode) are provided on the front surface of the semiconductor chip 20.

The diode elements 221 to 224 are connected in anti-parallel to the switching elements 211 to 214. In other words, the diode elements 221 to 224 is connected to the switching elements 211 to 214 such that a forward direction of the diode elements 221 to 224 is opposite to a direction in which a normal current flows in the switching elements 211 to 214. In a case where the semiconductor chip 20 includes the diode elements 221 to 224, a cathode electrode is provided on the back surface of the semiconductor chip 20, and an anode electrode is provided on the front surface of the semiconductor chip 20.

The back surface of the semiconductor chip 20 is joined to the first circuit pattern 111 or the second circuit pattern 112 by a joining material. The joining material is, for example, solder or a sintered body. The sintered body contains, for example, Ag or Cu.

The front surface of the semiconductor chip 20 is electrically connected to the first circuit pattern 111 or the second circuit pattern 112 by the bonding wire 25. For example, one end of the bonding wire 25 is directly joined to an electrode provided on the front surface of the semiconductor chip 20, and the other end is directly joined to the first circuit pattern 111 or the second circuit pattern 112. The first circuit pattern 111 is electrically connected to the insert terminal 40, and the second circuit pattern 112 is electrically connected to the outsert terminal 50. FIG. 3 does not illustrate a joint portion of gate terminal (G1 to G4 terminals), emitter sense terminal (Es1 to Es4 terminals), and the C terminals 31 and 34. In a case where the emitter electrodes of different semiconductor chips 20 have substantially the same potential, the emitter sense terminals are not required to be provided, and an emitter sense terminal may be a common terminal. For example, in an equivalent circuit in FIG. 10, since the emitter electrode of switching element 2311 and the emitter electrode of switching element 2321 have substantially the same potential, the emitter sense terminal may be configured as one common terminal.

### First Modification of First Preferred Embodiment

The semiconductor chip 20 according to a first modification of the first preferred embodiment includes an IGBT. The joint portion 111A of the first circuit pattern 111 illustrated in FIG. 3 has substantially the same potential as the gate electrode. The joint portion 112A of the second circuit pattern 112 has substantially the same potential as the emitter electrode. The internal connection end 43 of the insert terminal 40 is joined to the joint portion 111A of the first circuit pattern 111. In other words, the first electrode electrically connected to the insert terminal 40 is a gate electrode. The internal connection end 51A of the outsert terminal 50 is joined to the joint portion 112A of the second circuit pattern 112. In other words, the second electrode electrically connected to the outsert terminal 50 is an emitter electrode. As illustrated in FIG. 5, the outsert terminal 50 and the insert terminal 40 are disposed close to each other. Such a configuration reduces a magnetic flux passing through a loop between a gate and an emitter. As a result, a potential fluctuation of the gate is reduced.

### Second Modification of First Preferred Embodiment

As in the first modification, the insert terminal 40 is electrically connected to a gate terminal, and the outsert terminal 50 is electrically connected to an emitter terminal. As illustrated in FIGS. 5 to 7, the insert terminal 40 and the conductive portion 51 of the outsert terminal 50 have a skew positional relationship. That is, the conductive portion 51 of the outsert terminal 50 intersects the insert terminal 40 in plan view and side view. The number of intersections may be two or more. Such a configuration further reduces the magnetic flux passing through the loop.

### Third Modification of First Preferred Embodiment

As illustrated in FIG. 5, the internal connection end 43 of the insert terminal 40 and the internal connection end 51A of the outsert terminal 50 may have an L shape. The contact area between the internal connection ends 43 and 51A and the conductive layer 11 increases, and are easily joined. In addition, joining stability is increased, and variations in joining strength are reduced.

### Fourth Modification of First Preferred Embodiment

The conductive portion 51 of the outsert terminal 50 may be softer than the second circuit pattern 112. For example, by performing an annealing treatment or the like on the outsert terminal 50, the outsert terminal 50 becomes softer than the second circuit pattern 112. Such an outsert terminal 50 absorbs positional deviation due to curvature or waviness of the conductive layer-attached insulating substrate 10. As a result, the internal connection end 51A of the outsert terminal 50 and the second circuit pattern 112 are stably joined to each other.

### Second Preferred Embodiment

FIG. 11 is a perspective view illustrating a configuration of the insert terminal 40 and the outsert terminal 50 according to a second preferred embodiment.

The insert terminal 40 includes a plurality of protrusions 41 and a plurality of through holes 42. Each of the protrusions 41 protrudes to an inner side of the case 30 and is exposed from the case 30. The through hole 42 is provided in the protrusion 41, that is, a portion exposed from the case 30. The outsert terminal 50 includes a plurality of projections 53 electrically insulated from the conductive portion 51. The plurality of projections 53 is respectively inserted into the plurality of through holes 42. A mode of insertion is similar to the mode in FIGS. 6 and 9.

Such a configuration further reduces the inclination or positional deviation of the outsert terminal 50. The internal connection end 51A of the outsert terminal 50 is stably joined to the second circuit pattern 112 of the conductive layer-attached insulating substrate 10. As a result, for example, the density of mounting is increased.

As illustrated in FIG. 2 or 4, the semiconductor device is provided with a plurality of insert terminals 40. At least one through hole 42 may be provided in each of the plurality of insert terminals 40. The plurality of through holes 42 may be deviated from each other in a height direction (up-down direction). In this case, the outsert terminal 50 has a shape corresponding to the shape of the insert terminal 40 into which the projection 53 is to be inserted. For example, each of the plurality of projections 53 has a configuration corresponding to the position (height) of each of the plurality of through holes 42.

### Third Preferred Embodiment

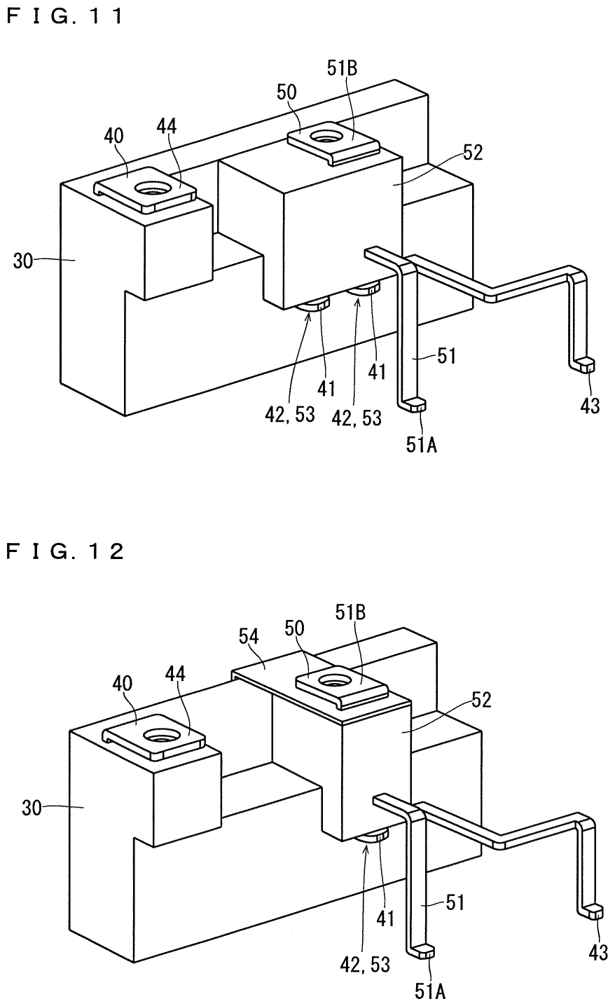

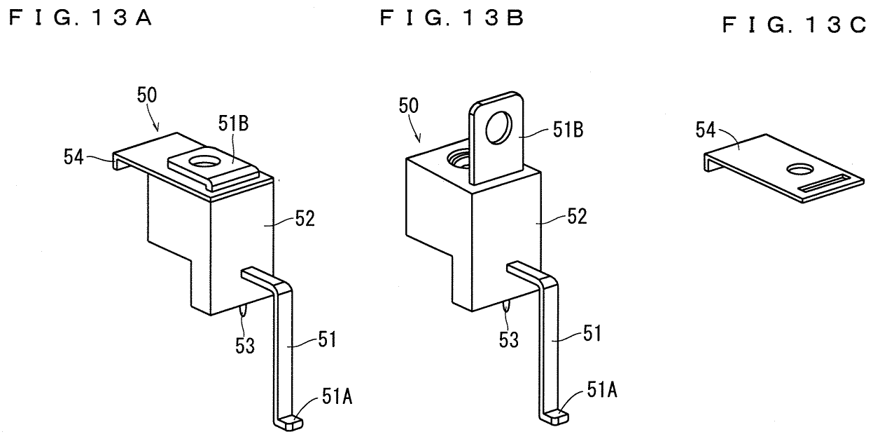

FIG. 12 is a perspective view illustrating a configuration of the insert terminal 40 and the outsert terminal 50 according to a third preferred embodiment. FIG. 13A is a perspective view illustrating a configuration of the outsert terminal 50.

The outsert terminal 50 includes a hook 54 that is hooked and held by the case 30. The hook 54 includes, for example, the same material as the insulating portion 52, and is formed on the insulating portion 52. In this case, the hook 54 is formed when the outsert terminal 50 is molded.

Such a configuration further reduces the inclination or positional deviation of the outsert terminal 50 at the time of joining the internal connection end 51A and the second circuit pattern 112. As a result, the joining is further stabilized, and the density of mounting is increased.

FIG. 13B is a perspective view illustrating a configuration of the outsert terminal 50. FIG. 13C is a perspective view illustrating a configuration of the hook 54. The outsert terminal 50 may have a configuration in which the hook 54 illustrated in FIG. 13C is combined with the external connection end 51B illustrated in FIG. 13B. The hook 54 is fixed to the external connection end 51B with an adhesive or a screw. Alternatively, the hook 54 is sandwiched and fixed between the bent external connection end 51B and the insulating portion 52. Alternatively, the hook 54 is fixed by a combination of these fixing means.

### Fourth Preferred Embodiment

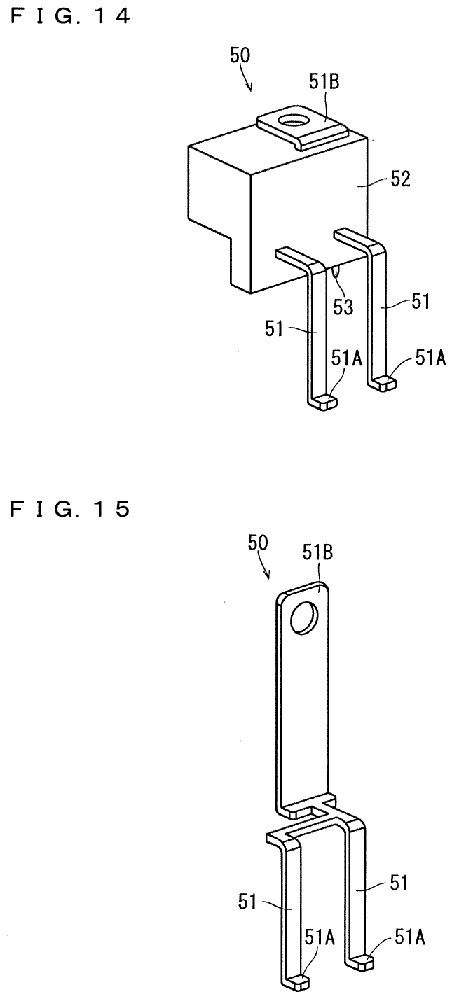

FIG. 14 is a perspective view illustrating a configuration of the outsert terminal 50 according to a fourth preferred embodiment. FIG. 15 is a perspective view illustrating a configuration of the conductive portion 51 of the outsert terminal 50.

The outsert terminal 50 includes a plurality of internal connection ends 51A. The plurality of internal connection ends 51A is joined to the second circuit pattern 112 as in the other preferred embodiments.

Such a configuration further reduces the inclination or positional deviation of the outsert terminal 50 at the time of joining the internal connection end 51A and the second circuit pattern 112. As a result, the joining is further stabilized.

### Fifth Preferred Embodiment

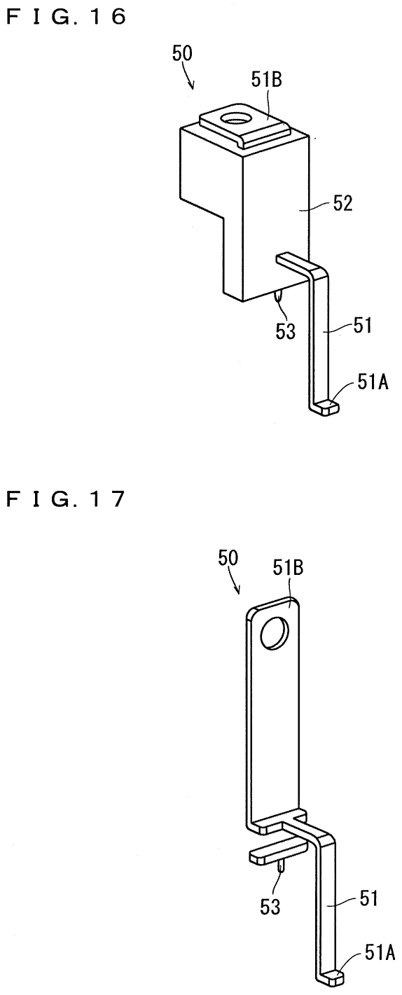

FIG. 16 is a perspective view illustrating a configuration of the outsert terminal 50 according to a fifth preferred embodiment. FIG. 17 is a perspective view illustrating a configuration of the conductive portion 51 and the projection 53 of the outsert terminal 50.

The projection 53 includes metal having high rigidity such as Cu, for example. The projection 53 is electrically insulated from the conductive portion 51 by the insulating portion 52.

Since the projection 53, which includes metal, has a certain strength. When the projection 53 is inserted into the through hole 42 or when the outsert terminal 50 is joined to the second circuit pattern 112, damage to the projection 53 due to stress or the like is prevented, and assemblability is improved.

### Sixth Preferred Embodiment

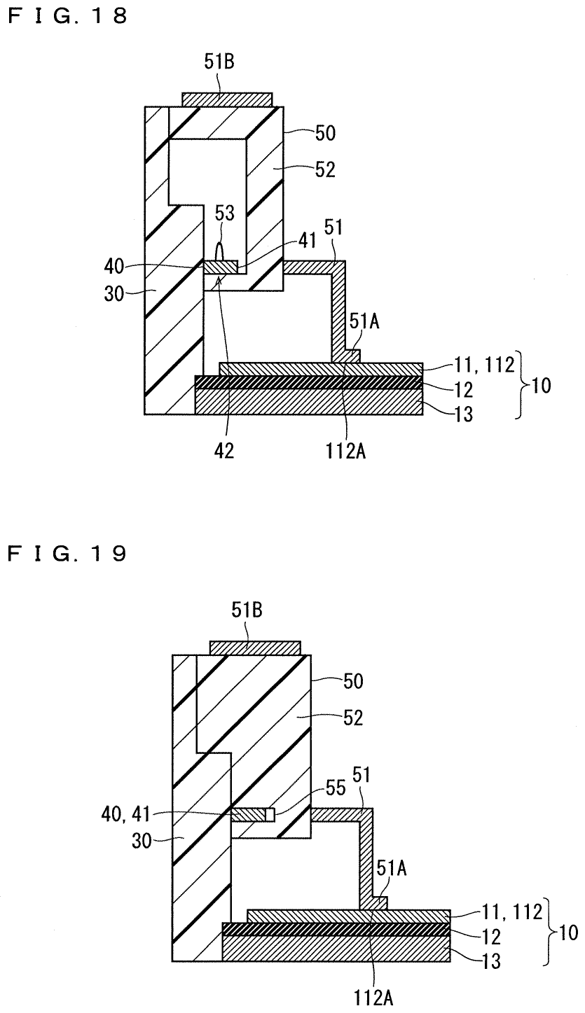

FIG. 18 is a side view illustrating a configuration of the insert terminal 40 and the outsert terminal 50 according to a sixth preferred embodiment.

The projection 53 of the outsert terminal 50 is formed upward. The projection 53 is inserted into the through hole 42 from below the through hole 42 of the insert terminal 40. The insulating portion 52 of the outsert terminal 50 is in contact with a lower surface of the insert terminal 40 at least at one location. In FIG. 18, the insulating portion 52 is in contact with a lower surface of the protrusion 41 of the insert terminal 40 in which the through hole 42 is formed.

A step of inserting the projection 53 into the through hole 42 is performed before a step of joining the internal connection end 51A of the outsert terminal 50 and the second circuit pattern 112. After the projection 53 is inserted into the through hole 42, the second circuit pattern 112 is pressed against a lower surface of the internal connection end 51A. At this time, the outsert terminal 50 receives a force from the up-down direction by the protrusion 41 of the insert terminal 40 and the conductive layer-attached insulating substrate 10. In this state, the internal connection end 51A is joined to the second circuit pattern 112. The internal connection end 51A may be directly joined to the second circuit pattern 112, or may be joined to the second circuit pattern 112 via a joining material (not illustrated) such as solder. Since the outsert terminal 50 is stabilized by the force applied from the up-down direction at the time of joining, variations in joining strength are reduced.

### Seventh Preferred Embodiment

FIG. 19 is a side view illustrating a configuration of the insert terminal 40 and the outsert terminal 50 according to a seventh preferred embodiment.

The outsert terminal 50 includes the conductive portion 51, the insulating portion 52, and a recess 55. The recess 55 is electrically insulated from the conductive portion 51. The recess 55 according to the seventh preferred embodiment is formed in the insulating portion 52. Therefore, the recess 55 is easily formed when the outsert terminal 50 is molded.

The insert terminal 40 includes the protrusion 41 protruding from the case 30. The protrusion 41 is inserted into the recess 55 of the outsert terminal 50. The protrusion 41 is in contact with the outsert terminal 50 at least at one location.

A step of inserting the protrusion 41 into the recess 55 is performed before the step of joining the internal connection end 51A of the outsert terminal 50 and the second circuit pattern 112. After the protrusion 41 is inserted into the recess 55, the second circuit pattern 112 is pressed against the lower surface of the internal connection end 51A. At this time, a bottom surface of the recess 55 of the outsert terminal 50 is pressed against the lower surface of the protrusion 41 of the insert terminal 40. In this state, the internal connection end 51A is joined to the second circuit pattern 112. The internal connection end 51A may be directly joined to the second circuit pattern 112, or may be joined to the second circuit pattern 112 via a joining material (not illustrated) such as solder. Since the outsert terminal 50 is stabilized by the force applied from the up-down direction at the time of joining, variations in joining strength are reduced.

### Eighth Preferred Embodiment

FIG. 20 is a side view illustrating a configuration of the insert terminal 40 and the outsert terminal 50 according to an eighth preferred embodiment.

The recess 55 of the outsert terminal 50 is formed upward from a lower surface of the insulating portion 52. The recess 55 is electrically insulated from the conductive portion 51. The recess 55 according to the eighth preferred embodiment is formed in the insulating portion 52. Therefore, the recess 55 is easily formed when the outsert terminal 50 is molded.

A distal end of the protrusion 41 of the insert terminal 40 is formed upward. The distal end of the protrusion 41 is inserted into the recess 55 of the outsert terminal 50.

A step of inserting the protrusion 41 into the recess 55 is performed before the step of joining the internal connection end 51A of the outsert terminal 50 and the second circuit pattern 112. After the protrusion 41 is inserted into the recess 55, the internal connection end 51A is joined to the second circuit pattern 112. The internal connection end 51A may be directly joined to the second circuit pattern 112, or may be joined to the second circuit pattern 112 via a joining material (not illustrated) such as solder. At the time of joining, the inclination or positional deviation of the outsert terminal 50 is further reduced. As a result, the joining is further stabilized.

### Ninth Preferred Embodiment

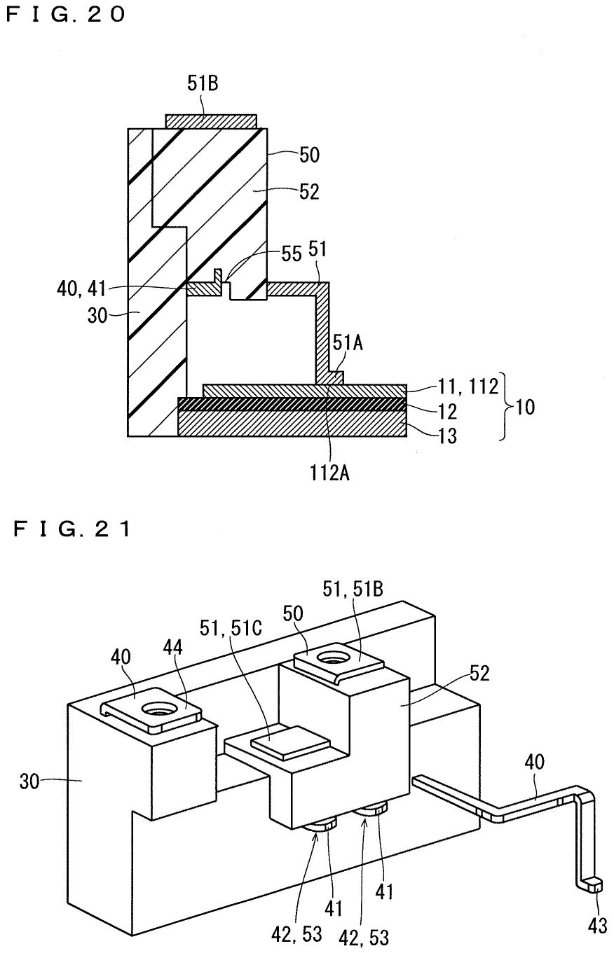

FIG. 21 is a perspective view illustrating a configuration of the insert terminal 40 and the outsert terminal 50 according to a ninth preferred embodiment.

The insert terminal 40 includes a plurality of protrusions 41 and a plurality of through holes 42. Each of the protrusions 41 protrudes to an inner side of the case 30 and is exposed from the case 30. The through hole 42 is provided in the protrusion 41, that is, a portion exposed from the case 30.

The outsert terminal 50 includes the conductive portion 51, the insulating portion 52, and a plurality of projections 53. The plurality of projections 53 is respectively inserted into the plurality of through holes 42 of the insert terminal 40. A mode of insertion is similar to the mode in FIGS. 6 and 9.

The conductive portion 51 includes the external connection end 51B and a wire bond area 51C. The wire bond area 51C is provided on the upper surface of the insulating portion 52. The wire bond area 51C is formed, for example, as a component integrated with the external connection end 51B. Alternatively, the wire bond area 51C may be formed as a component different from the external connection end 51B and electrically connected to the external connection end 51B. The wire bond area 51C is electrically insulated from the projection 53 of the outsert terminal 50.

The wire bond area 51C is electrically connected to any one or more of the conductive layer 11 of the conductive layer-attached insulating substrate 10, a surface electrode of the switching elements 211 to 214, or a surface electrode of the diode elements 221 to 224 by the bonding wire 25 (not illustrated).

The semiconductor device according to the ninth preferred embodiment may have the following connection configuration. The first circuit pattern 111 is electrically connected to any one of the collector electrode, the emitter electrode, or the gate electrode of the semiconductor chip 20. The insert terminal 40 is electrically connected to the first circuit pattern 111.

The wire bond area 51C is electrically connected by the bonding wire 25 to an electrode different from the gate electrode or the emitter electrode of the semiconductor chip 20 electrically connected to the first circuit pattern 111. For example, one end of the bonding wire 25 is directly joined to the wire bond area 51C, and the other end is directly joined to an electrode different from the electrode of the semiconductor chip 20 electrically connected to the first circuit pattern 111.

Such a connection configuration by the bonding wire 25 reduces an influence of curvature or waviness of the conductive layer-attached insulating substrate 10. Assemblability such as electrical connection is facilitated.

Since the plurality of projections 53 is respectively inserted into the plurality of through holes 42, the inclination or positional deviation of the outsert terminal 50 is further reduced. Since the outsert terminal 50 is firmly fixed, a stronger force can be applied when wire bonding is performed on the outsert terminal 50. For example, the bonding wire 25 including a harder material can be stably joined. The number of options in the wire bonding step increases.

### Tenth Preferred Embodiment

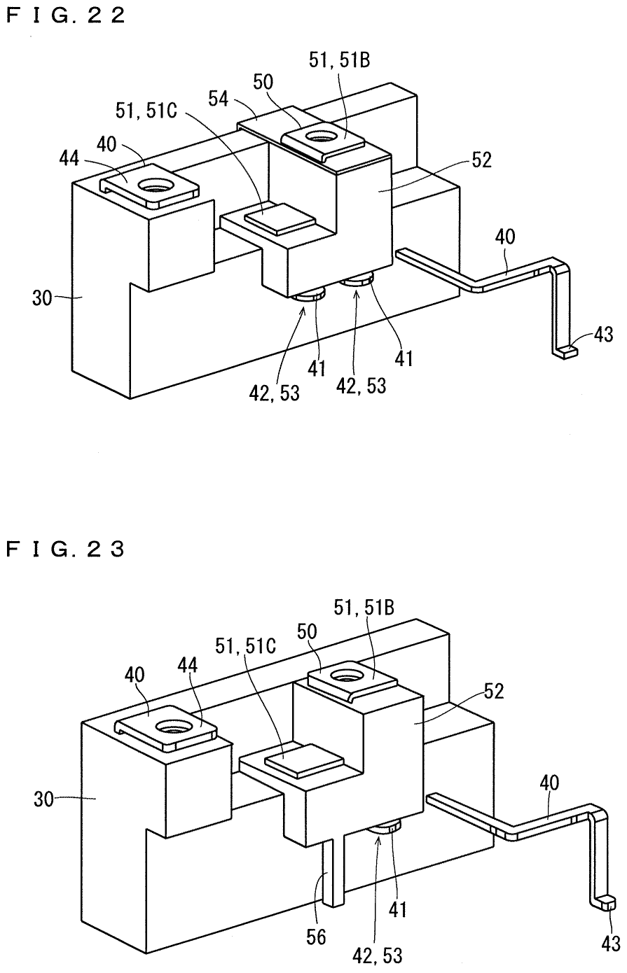

FIG. 22 is a perspective view illustrating a configuration of the insert terminal 40 and the outsert terminal 50 according to a tenth preferred embodiment.

The outsert terminal 50 includes the hook 54 in addition to the configuration of the ninth preferred embodiment. The hook 54 is hooked and held on the case 30. Other configurations are the same as the configuration of the ninth preferred embodiment.

The outsert terminal 50 is more firmly fixed to the case 30 by the hook 54. Therefore, wire bonding to the outsert terminal 50 can be performed with a stronger force. As in the ninth preferred embodiment, the bonding wire 25 including, for example, a harder material can be stably joined. The number of options in the wire bonding step increases.

### Eleventh Preferred Embodiment

FIG. 23 is a perspective view illustrating a configuration of the insert terminal 40 and the outsert terminal 50 according to an eleventh preferred embodiment.

The outsert terminal 50 includes a support column 56 in addition to the conductive portion 51, the insulating portion 52, and the projection 53. The support column 56 is electrically insulated from the conductive portion 51 including the wire bond area 51C. The bottom surface of the support column 56 is in contact with the conductive layer 11 or the insulating layer 12 of the conductive layer-attached insulating substrate 10. That is, the support column 56 is in contact with the conductive layer-attached insulating substrate 10. Other configurations are the same as the configuration of the ninth preferred embodiment.

Since the support column 56 is in contact with the conductive layer-attached insulating substrate 10, wire bonding can be performed on the outsert terminal 50 with a stronger force. As in the ninth preferred embodiment, the bonding wire 25 including, for example, a harder material can be stably joined. The number of options in the wire bonding step increases.

### Twelfth Preferred Embodiment

The semiconductor chip 20 is a power semiconductor chip. The switching elements 211 to 214 or the diode elements 221 to 224 may include a normal semiconductor such as silicon (Si), or may include a wide band gap semiconductor such as silicon carbide (SiC), gallium nitride (GaN), or diamond.

In a case where the material of the semiconductor chip 20 is a wide band gap semiconductor, the operation under high temperature and high voltage is stably performed, and a switching speed is increased. In addition, the semiconductor device is downsized.

In the present disclosure, the preferred embodiments can be freely combined, and the preferred embodiments can be appropriately modified or omitted.

Hereinafter, various modes of the present disclosure will be collectively described as appendixes.

### (Appendix 1)

A semiconductor device comprises
a semiconductor chip including a first electrode and a second electrode,
a first terminal electrically connected to the first electrode of the semiconductor chip,
a case that accommodates the semiconductor chip and in which a part of the first terminal is embedded, and
a second terminal including a conductive portion electrically connected to the second electrode of the semiconductor chip and a projection electrically insulated from the conductive portion,
wherein the first terminal includes a through hole provided in a portion exposed from the case, and
the projection is inserted into the through hole.

### (Appendix 2)

The semiconductor device according to Appendix 1, further comprises
a first circuit pattern electrically connected to the first terminal and the first electrode of the semiconductor chip, and
a second circuit pattern electrically connected to the second terminal and the second electrode of the semiconductor chip,
wherein the first electrode is any one of a collector electrode, an emitter electrode, or a gate electrode of the semiconductor chip, and
the second electrode is an electrode different from the first electrode of the collector electrode, the emitter electrode, or the gate electrode of the semiconductor chip.

### (Appendix 3)

The semiconductor device according to Appendix 1 or 2, further comprises a circuit pattern electrically connected to the second terminal and the second electrode of the semiconductor chip
wherein the second terminal includes a connection end joined to the circuit pattern, and
the connection end has an L shape.

### (Appendix 4)

In the semiconductor device according to any one of Appendixes 1 to 3,
the first electrode of the semiconductor chip is a gate electrode,
the second electrode of the semiconductor chip is an emitter electrode, and
the first terminal and the second terminal are disposed close to each other.

### (Appendix 5)

In the semiconductor device according to any one of Appendixes 1 to 4, the conductive portion of the second terminal intersects with the first terminal at least at one location in at least one of a plan view or a side view.

### (Appendix 6)

The semiconductor device according to any one of Appendixes 1 to 5, further comprises
a circuit pattern electrically connected to the second terminal and the second electrode of the semiconductor chip,
wherein the conductive portion of the second terminal is softer than the circuit pattern.

### (Appendix 7)

In the semiconductor device according to any one of Appendixes 1 to 6,
the first terminal includes a plurality of through holes provided in the portion exposed from the case,
the second terminal includes a plurality of projections electrically insulated from the conductive portion, and
the plurality of projections is respectively inserted into the plurality of through holes.

### (Appendix 8)

In the semiconductor device according to any one of Appendixes 1 to 7, the second terminal includes a hook that is hooked and held on the case.

### (Appendix 9)

The semiconductor device according to Appendixes 1 to 8, further comprises a circuit pattern electrically connected to the second terminal and the second electrode of the semiconductor chip,
wherein the second terminal includes a plurality of connection ends joined to the circuit pattern.

### (Appendix 10)

In the semiconductor device according to any one of Appendixes 1 to 9, the projections include metal.

### (Appendix 11)

In the semiconductor device according to any one of Appendixes 1 to 10,
the second terminal includes an insulating portion that covers a part of the conductive portion and is held by the case,
the projections are formed upward and are inserted into the through holes from below the through holes, and
the insulating portion is in contact with a lower surface of the first terminal at least at one location.

### (Appendix 12)

A semiconductor device comprises
a semiconductor chip including a first electrode and a second electrode,
a first terminal electrically connected to the first electrode of the semiconductor chip,
a case that accommodates the semiconductor chip and in which a part of the first terminal is embedded, and
a second terminal including a conductive portion electrically connected to the second electrode of the semiconductor chip and a recess electrically insulated from the conductive portion,
wherein the first terminal includes a protrusion that protrudes from the case, and
the protrusion is inserted into the recess and is in contact with the second terminal at least at one location.

### (Appendix 13)

A semiconductor device comprises
a semiconductor chip,
a conductive layer electrically connected to any one of a collector electrode, an emitter electrode, or a gate electrode of the semiconductor chip,
a first terminal electrically connected to the conductive layer,
a case that accommodates the semiconductor chip and in which a part of the first terminal is embedded, and
a second terminal including a wire bond area and a projection electrically insulated from the wire bond area,
wherein the first terminal includes a through hole provided in a portion exposed from the case,
the projection is inserted into the through hole, and
the wire bond area is electrically connected by a bonding wire to a circuit pattern different from the conductive layer or an electrode different from the gate electrode or the emitter electrode of the semiconductor chip electrically connected to the conductive layer.

### (Appendix 14)

In the semiconductor device according to Appendix 13,
the first terminal includes a plurality of through holes provided in the portion exposed from the case,
the second terminal includes a plurality of projections electrically insulated from the wire bond area, and
the plurality of projections is respectively inserted into the plurality of through holes.

### (Appendix 15)

In the semiconductor device according to Appendix 13 or 14, the second terminal includes a hook that is hooked and held on the case.

### (Appendix 16)

The semiconductor device according to any one of Appendixes 13 to 15, further comprises a conductive layer-attached insulating substrate that includes the circuit pattern and holds the semiconductor chip,
wherein the second terminal includes a support column electrically insulated from the wire bond area, and
the support column is in contact with the conductive layer-attached insulating substrate.

### (Appendix 17)

In the semiconductor device according to any one of Appendixes 1 to 16, the semiconductor chip includes a power semiconductor chip constituted by a wide band gap semiconductor.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor chip including a first electrode and a second electrode;
a first terminal electrically connected to the first electrode of the semiconductor chip;
a case that accommodates the semiconductor chip and in which a part of the first terminal is embedded; and
a second terminal including a conductive portion electrically connected to the second electrode of the semiconductor chip and a projection electrically insulated from the conductive portion,
wherein the first terminal includes a through hole provided in a portion exposed from the case, and
the projection is inserted into the through hole.

2. The semiconductor device according to claim 1, further comprising:
a first circuit pattern electrically connected to the first terminal and the first electrode of the semiconductor chip; and
a second circuit pattern electrically connected to the second terminal and the second electrode of the semiconductor chip,
wherein the first electrode is any one of a collector electrode, an emitter electrode, or a gate electrode of the semiconductor chip, and
the second electrode is an electrode different from the first electrode of the collector electrode, the emitter electrode, or the gate electrode of the semiconductor chip.

3. The semiconductor device according to claim 1, further comprising a circuit pattern electrically connected to the second terminal and the second electrode of the semiconductor chip,
wherein the second terminal includes a connection end joined to the circuit pattern, and
the connection end has an L shape.

4. The semiconductor device according to claim 1, wherein
the first electrode of the semiconductor chip is a gate electrode,
the second electrode of the semiconductor chip is an emitter electrode, and
the first terminal and the second terminal are disposed close to each other.

5. The semiconductor device according to claim 1, wherein the conductive portion of the second terminal intersects with the first terminal at least at one location in at least one of a plan view or a side view.

6. The semiconductor device according to claim 1, further comprising a circuit pattern electrically connected to the second terminal and the second electrode of the semiconductor chip,
wherein the conductive portion of the second terminal is softer than the circuit pattern.

7. The semiconductor device according to claim 1, wherein
the first terminal includes a plurality of through holes provided in the portion exposed from the case,
the second terminal includes a plurality of projections electrically insulated from the conductive portion, and
the plurality of projections is respectively inserted into the plurality of through holes.

8. The semiconductor device according to claim 1, wherein the second terminal includes a hook that is hooked and held on the case.

9. The semiconductor device according to claim 1, further comprising a circuit pattern electrically connected to the second terminal and the second electrode of the semiconductor chip,
wherein the second terminal includes a plurality of connection ends joined to the circuit pattern.

10. The semiconductor device according to claim 1, wherein the projections include metal.

11. The semiconductor device according to claim 1, wherein
the second terminal includes an insulating portion that covers a part of the conductive portion and is held by the case,
the projections are formed upward and are inserted into the through holes from below the through holes, and
the insulating portion is in contact with a lower surface of the first terminal at least at one location.

12. A semiconductor device comprising:
a semiconductor chip including a first electrode and a second electrode;
a first terminal electrically connected to the first electrode of the semiconductor chip;
a case that accommodates the semiconductor chip and in which a part of the first terminal is embedded; and
a second terminal including a conductive portion electrically connected to the second electrode of the semiconductor chip and a recess electrically insulated from the conductive portion,
wherein the first terminal includes a protrusion that protrudes from the case, and
the protrusion is inserted into the recess and is in contact with the second terminal at least at one location.

13. A semiconductor device comprising:
a semiconductor chip;
a conductive layer electrically connected to any one of a collector electrode, an emitter electrode, or a gate electrode of the semiconductor chip;
a first terminal electrically connected to the conductive layer;
a case that accommodates the semiconductor chip and in which a part of the first terminal is embedded; and
a second terminal including a wire bond area and a projection electrically insulated from the wire bond area,
wherein the first terminal includes a through hole provided in a portion exposed from the case,
the projection is inserted into the through hole, and
the wire bond area is electrically connected by a bonding wire to a circuit pattern different from the conductive layer or an electrode different from the gate electrode or the emitter electrode of the semiconductor chip electrically connected to the conductive layer.

14. The semiconductor device according to claim 13, wherein
the first terminal includes a plurality of through holes provided in the portion exposed from the case,
the second terminal includes a plurality of projections electrically insulated from the wire bond area, and
the plurality of projections is respectively inserted into the plurality of through holes.

15. The semiconductor device according to claim 13, wherein the second terminal includes a hook that is hooked and held on the case.

16. The semiconductor device according to claim 13, further comprising a conductive layer-attached insulating substrate that includes the circuit pattern and holds the semiconductor chip,
wherein the second terminal includes a support column electrically insulated from the wire bond area, and
the support column is in contact with the conductive layer-attached insulating substrate.

17. The semiconductor device according to claim 1, wherein the semiconductor chip includes a power semiconductor chip constituted by a wide band gap semiconductor.

18. The semiconductor device according to claim 12, wherein the semiconductor chip includes a power semiconductor chip constituted by a wide band gap semiconductor.

19. The semiconductor device according to claim 13, wherein the semiconductor chip includes a power semiconductor chip constituted by a wide band gap semiconductor.
